(19) United States
(12) Patent Application Publication
(10) Pub. No.: US 2017/0144883 A1
(43) Pub. Date: May 25, 2017

(54) MICROELECTRONIC PACKAGE AND METHOD OF MANUFACTURING A MICROELECTRONIC PACKAGE

(71) Applicants: EPCOS AG, Munich (DE); Commissariat à l'énergie atomique et aux énergies alternatives, Paris (FR)

(72) Inventors: Gudrun HENN, Ebenhausen (DE); Marcel GIESEN, Munich (DE); Arnoldus DEN DEKKER, CP Beuningen (NL); Jean-Louis PORNIN, Crolles (FR); Damien SAINT-PATRICE, Chabeuil (FR); Bruno REIG, Moirans (FR)

(73) Assignees: EPCOS AG, Munich (DE); Commissariat a l'energie atomique et aux energies alternatives, Paris (FR)

(21) Appl. No.: 15/318,969

(22) PCT Filed: Jun. 16, 2014
(86) PCT No.: PCT/EP2014/062551

§ 371 Date: Dec. 14, 2016

(51) Int. Cl. B81C 1/00; B81B 7/00

(52) U.S. Cl. CPC B81C 1/00293; B81B 7/0041; B81B 2203/0315; B81C 2203/0145; B81C 2201/0176; B81C 2201/0109; B81C 2201/013

(57) ABSTRACT

The present invention concerns a microelectronic package (1) comprising a microelectronic structure (2) having at least a first opening (3) and defining a first cavity (4), a capping layer (9) having at least a second opening (10) and defining a second cavity (11) which is connected to the first cavity (4), wherein the capping layer (9) is arranged over the microelectronic structure (2) such that the second opening (10) is arranged over the first opening (3), and a sealing layer (13) covering the second opening (10), thereby sealing the first cavity (4) and the second cavity (11). Moreover, the present invention concerns a method of manufacturing the microelectronic package (1).

The present invention concerns a microelectronic package such as a MEMS device(MEMS=micro-electro mechanical system), a MOEMS device (MOEMS=Micro-Opto-Electro-Mechanical System), a NEMS device (NEMS=Nanoelectromechanical system), a NOEMS device (NOEMS=Nano-Opto-Electro-Mechanical System) or any other device such as an acoustic-type or a sensor-type device having one or several cavities with a controlled atmosphere or with a vacuum. Further, the present invention concerns a method of manufacturing the microelectronic package.

The microelectronic package comprises a microelectronic structure arranged in a cavity. Such microelectronic packages can be formed by various packaging technologies.

One method of manufacturing microelectronic packages is the thin film packaging technology which is also known as zero level packaging. In this technology, the microelectronic structure is embedded in a sacrificial layer, the sacrificial layer is structured, a capping layer is arranged on the sacrificial layer and in a last step, the sacrificial layer is removed via etching or via dissolving using a solvent. For this purpose, an opening in the capping layer is required to introduce the solvent or the etching atmosphere. This opening has to be sealed after the etching or dissolving is completed.

However, many microelectronic packages comprise very sensitive microelectronic structures. Thus, it has to be ensured that no material is deposited on the microelectronic structure during the sealing of the opening. Otherwise, this material would influence the performance of the microelectronic structure.

US2012/0161255A1 suggests a method of sealing a MEMS package.

It is an object of the present invention to provide a microelectronic package with improved properties, e.g. by allowing for a faster manufacturing process or by saving chip area. Further, it is another object to provide a method of manufacturing such a microelectronic package.

This object is solved by a microelectronic package according to present claim 1. Further, the second object is solved by a method according to the second independent claim.

A microelectronic package is provided which comprises a microelectronic structure having at least a first opening and defining a first cavity, a capping layer having at least a second opening and defining a second cavity which is connected to the first cavity, wherein the capping layer is arranged over the microelectronic structure such that the second opening is arranged over the first opening, and a sealing layer covering the second opening, thereby sealing the first cavity and the second cavity.

The microelectronic structure may be a MEMS structure, e.g. SAW filter (SAW=Surface Acoustic Wave) or resonator, a BAW filter (BAW=Bulk Acoustic Wave) or resonator, an accelerometer, a gyroscope, a micro tube, a sensor, a mirror, a resonator, a mechanical filter, a switch, a circuit, a cantilever beam, a bridge beam, a capacitor switch, a contact switch or a relay. However, the invention is not limited to these MEMS structures or other types of MEMS structures known to one skilled in the art. The microelectronic structure may e.g. also be a MOEMS structure, a NEMS structure or a NOEMS structure. Typically, the microelectronic structure may comprise oscillating elements or elements that are designed to move very fast.

The microelectronic structure may comprise a free-standing element which is arranged in the cavities. In particular, the free-standing element is neither in direct contact with the capping layer nor in direct contact with a carrier substrate on which the microelectronic structure is arranged. In particular, the free-standing element is encapsulated inside the first and the second cavity.

The first opening may be a release hole. In particular, the microelectronic structure may be formed on a first sacrificial layer which is removed in a later manufacturing step. The first opening maybe used during manufacturing as a release hole to introduce and, later, to remove a solvent or an etching atmosphere which dissolves or etches the first sacrificial layer.

Similarly, the second opening may also be a release hole. The capping layer may be formed on a second sacrificial layer which is removed in a later manufacturing step. The second opening may be used as a release hole to introduce and, later, to remove a solvent or an etching atmosphere which dissolve or etch the second sacrificial layer.

The term “the second opening being arranged over the first opening” is to be understood such that a straight line can be plotted through the two openings wherein said straight line is parallel to a surface normal of the microelectronic structure and/or a surface normal of the capping layer. In other words, the second opening of the capping layer is arranged on top of the first opening of the microelectronic structure.

Preferably, the second opening is arranged concentric with the first opening.

In particular, the second opening may be arranged completely over the first opening. Accordingly, the second opening may be arranged completely inside the first opening when both openings are projected into one plane. In other words, no part of the second opening may be arranged over a part of the microelectronic structure which is free from the first opening.

This design ensures that any unwanted material that enters the cavities during sealing of the second opening will not be deposited onto the microelectronic structure. Instead, the unwanted material will pass through the first opening in the microelectronic structure. Thus, this material will be deposited elsewhere, e.g. on a carrier substrate.

For example, when the sealing layer is constructed via chemical vapor deposition (CVD), material will enter into the cavities during the manufacturing process. However, this material will not deposit on the microelectronic structure, but on underlying elements as the material will pass through the second opening and afterwards through the first opening. Thus, the deposited material will not influence the microelectronic structure and will not degrade its performance.

Accordingly, the design of the two openings is chosen such that any unwanted deposition below the combined holes which may occur during sealing is much smaller in its lateral expansion than the first opening of the microelectronic structure first opening. As a consequence, no effect on the movement of the microelectronic structure can be found. Thus, the proposed arrangement of the first and the second opening increases the amount of possible processes for sealing the cavities as in many sealing processes it is inevitable to have some unwanted depositions, e.g. in CVD.

Moreover, as the second opening is arranged above the first opening, a microelectronic package is constructed wherein no extra chip space is required for the arrangement of the second opening. Thus, this design does not increase the space requirements for the microelectronic package, thereby saving chip area. In particular, the lateral dimensions of the microelectronic package are not increased due to the arrangement of the second opening.

The capping layer and the sealing layer may be formed in thin film technology. Thus, multiple microelectronic structures are formed on a wafer and sealed by the capping layer and the sealing layer before the microelectronic packages are separated, e.g. by cutting the wafer. In particular, when the microelectronic packages are formed and sealed on wafer level, the present design allows for distributing the second openings evenly over the wafer area. This results in a fast processing.

Moreover, thin film technology provides microelectronic packages with a low height. A low height of a microelectronic package is a requirement in a lot of applications.

The capping layer may be separated from the microelectronic structure by a spacer layer. The capping layer may be designed such that it seals the first and the second cavity when the second opening is closed. The sealing layer closes the second opening, thereby sealing the cavities. Further, the sealing layer may be arranged on the sides of the microelectronic package and may extend onto a carrier substrate.

In one embodiment, the second opening has a width which is smaller than a width of the first opening. In this context, the width of the second opening may be understood as the maximum width of the second opening. The width of the first opening may refer to the maximum width of the first opening. A width of an opening corresponds to the distance between two boundary points of said opening. Thus, the maximum width of an opening corresponds to the distance between the two boundary points of the opening which are furthest apart from each other.

The first and the second opening may each have all kinds of shapes, e.g. a circular shape, a rectangular shape or a quadratic shape. If the first and the second opening have a circular shape their width corresponds to the diameter of the respective circle.

The second opening having a width which is smaller than a width of the first opening further helps to ensure that no unwanted depositions occur on the microelectronic structure in case material enters through the second opening. Even if the unwanted material spreads out in a sideways direction after entering the cavity, it will not be deposited on the microelectronic structure.

In particular, the width of the first opening may be at least twice as big as the width of the second opening. Preferably, the width of the first opening may be at least five times as big as the width of the second opening. The smaller the ratio of the width of the second opening to the width of the first opening is, the less likely is an unwanted deposition on the microelectronic structure of material entering through the second opening.

Moreover, when the width of the second opening is small, the manufacturing step of sealing the second cavity can be carried out faster. Thus, a small width of the second opening allows for a faster manufacturing.

The width of the second opening in the capping layer may be between 1 μm and 8 μm, preferably between 2 μm and 6 μm. The width of the first opening in the microelectronic structure may be bigger than 8 μm, preferably bigger than 10 μm.

In one embodiment, the sealing layer may comprise an inorganic material. In particular, the sealing layer may consist of an inorganic material. For example, the sealing layer may consist of SiO₂. Inorganic materials provide various advantages. For example, a sealing layer comprising an inorganic material forms a hermetic seal. Hermetic seals do not allow water to enter into the cavity.

Further, the presence of organic materials may degrade the reliability of the microelectronic structure. In contrast to this, inorganic materials do not influence the microelectronic structure.

The sealing layer may comprise multiple sub-layers. Each of said sub-layers may comprise an inorganic materials. Each of said sub-layers may also consist of an inorganic material. The sealing layer may comprise at least one of silicon dioxide, silicon hydride and silicon nitride. The sealing layer may also comprise dielectric materials and/or metals.

The sealing layer may be formed in one step or in two or more steps. The sealing layer may be formed by first reducing the width of the second opening, e.g. by depositing material at the edge of the second opening, and afterwards completely closing the second opening. The step of closing the second opening may further comprise sub-steps wherein different inorganic materials are applied in different process sub-steps.

According to a second aspect of the present invention, a method of manufacturing a microelectronic package is proposed. The microelectronic package manufactured by this method may be the above-disclosed microelectronic package. Thus, any structural or functional feature disclosed with respect to the microelectronic package may also apply with respect to the method. Vice versa, any structural or functional feature disclosed with respect to the method may also apply with respect to the microelectronic package.

Further, the capping layer may comprise more than one second opening and the microelectronic structure may comprise more than one first opening, wherein each of the second openings is arranged either over one of the first openings or arranged in a section of the capping layer which does not overlap with the microelectronic structure. For example, the microelectronic structure may not extend over the full width of the microelectronic package. Thus, there may be a section adjacent to the microelectronic structure and inside the microelectronic package which is free from the microelectronic structure. The second opening of the capping layer may be arranged over said section.

In any case, each of the second openings may be arranged such that it is not directly over the parts of the microelectronic structure which do not comprise the first openings. Thus, it is prevented that material that enters through one of the second openings is deposited directly on the microelectronic structure.

A method is provided comprising the following steps:
providing a microelectronic structure having at least a first opening and defining a first cavity,
forming a capping layer over the microelectronic structure wherein the capping layer has at least a second opening and defines a second cavity which is connected to the first cavity and wherein the capping layer is arranged such that the second opening is arranged over the first opening, and
covering the second opening with a sealing layer, thereby sealing the first cavity and the second cavity.

As discussed above, this method allows for manufacturing a microelectronic package with a minimal space requirement in lateral dimensions, thereby saving chip area. Further, this method ensures that unwanted deposition of the sealing layer is prevented on the microelectronic structure, thereby improving the quality of the manufactured packages.

In one embodiment, the sealing layer may be formed via chemical vapor deposition. The proposed design allows for the use of CVD as the design ensures that unwanted depositions of material which are inevitable in a CVD process cannot degrade the performance of the microelectronic structure.

In one embodiment, the method may comprise a step of etching the first opening into the microelectronic structure and
a step of removing a first sacrificial layer to form the first cavity. The first sacrificial layer may be removed after the first opening is etched into the microelectronic structure.

In one embodiment, the method may comprise a step of etching the second opening into the capping layer and, further, the method may comprise a step of removing a second sacrificial layer to form the second cavity. The second sacrificial layer may be removed after the second opening is etched into the capping layer.

In one embodiment, the capping layer and the sealing layer may be formed by a thin film technology. Thus, said layers may be formed on wafer level before separating the microelectronic packages. Thin film technology allows for constructing microelectronic packages with a low height.

In the following, the disclosed microelectronic package and the method are described in further detail with reference to the drawing, wherein

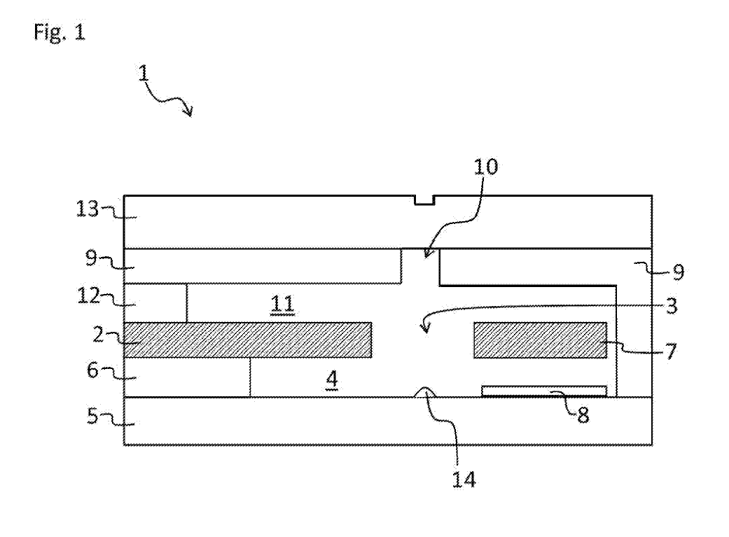

FIG. 1 shows cross-sectional view of a microelectronic package.

FIG. 1 shows a microelectronic package 1. The microelectronic package 1 comprises a microelectronic structure 2 which has a first opening 3 and which defines a first cavity 4. The microelectronic structure 2 is arranged above a substrate 5.

Further, the microelectronic package 1 comprises an anchor layer 6. The anchor layer 6 is arranged between the microelectronic structure 2 and the substrate 5. In particular, the anchor layer 6 forms an anchor for the microelectronic structure 2 such that some areas of the microelectronic structure 2 are connected to the substrate 5 via the anchor layer 6 and some areas of the microelectronic structure 2 are free-standing, thus being movable relative to the substrate 5. As an example of a typical microelectronic structure 2, FIG. 1 shows a microelectronic switch comprising a free-standing element 7 which is movable between two states by an actuator electrode 8 arranged on the substrate 5.

The first opening 3 of the microelectronic structure 2 is a release hole. The release hole is required during manufacturing of the microelectronic structure 2. In particular, the microelectronic structure 2 may be formed above a first sacrificial layer (not shown). The first sacrificial layer may be removed by etching or dissolving. Therefore, an etching atmosphere or a dissolvent is introduced through the first opening 3 and, later, the material of the first sacrificial layer is removed through the first opening 3.

Further, the microelectronic package 1 comprises a capping layer 9. The capping layer 9 has a second opening 10. The capping layer 9 defines a second cavity 11 which is connected to the first cavity 4. The capping layer 9 is arranged over the microelectronic structure 2 such that the second opening 10 is arranged over the first opening 3. In particular, the second opening 10 is concentric with the first opening 3.

The capping layer 9 defines a cavity comprising the first cavity 4 and the second cavity 11 wherein the microelectronic structure 2 is arrange inside said cavity. The cavity defined by the capping layer 9 is connected to the surroundings of the microelectronic package 1 only through the second opening 10 which is sealed in a later prosecution step.

The second opening 10 is a release opening. The second opening 10 is required during manufacturing of the microelectronic package 1. In particular, the capping layer 9 may be formed by removing a second sacrificial layer (not shown) wherein the material of the second sacrificial layer is removed through the second opening 10. The second sacrificial layer may be removed by etching or dissolving wherein an etching atmosphere or a dissolvent is introduced through the second opening 10.

Furthermore, the microelectronic structure 2 and the capping layer 9 are separated from each other by a spacer layer 12 which is arranged between the capping layer 9 and the microelectronic structure 2. The spacer layer 12 is arranged such that some areas of the capping layer 9 and the microelectronic structure 2 are free from the spacer layer 12. In particular, the spacer layer 12 is not arranged on the free-standing element 7 of the microelectronic structure 2. Further, the microelectronic package 1 comprises a sealing layer 13. The sealing layer 13 covers the second opening 10. Thereby, the sealing layer 13 seals the first and the second cavity 4, 11, such that the microelectronic structure 2 is arranged in a sealed cavity. In particular, the sealing layer 13 and the capping layer 9 may be formed using thin film technology.

Moreover, FIG. 1 shows material 14 which is deposited on the substrate 5. The deposited material 14 is so-called shadow-deposited material of the sealing layer.

The sealing layer 13 is formed using CVD. Thus, before the second opening 10 is closed, some of the material 14 of the sealing layer 13 will enter the first and second cavity 4, 11 through the second opening 10. This material 14 will deposit on the substrate 5. The first and the second opening 3, 10 are arranged such that it is ensured that the material 14 is not deposited on the microelectronic structure 2, but on the substrate 5. In particular, the material 14 will pass through the first opening 3 after entering through the second opening 10. As the material 14 is not deposited on the microelectronic structure 2, the material 14 does not influence the properties of the microelectronic structure 2. Thus, the performance of highly sensitive microelectronic structures 2 is not degraded by the material 14.

As the second opening 10 is above the first opening 3, the material 14 will pass through the first opening 3 after entering the second cavity 11 through the second opening 10. FIG. 1 shows an embodiment wherein the second opening 10 has a width that is smaller than the width of the first opening 3. In this embodiment, it is prevented that the material 14 is deposited on the microelectronic structure 2, even if the material 14 spreads out in a lateral direction after entering into the second cavity 11.

The sealing layer 13 is formed in one or more steps using CVD processes. Thus, the sealing layer 13 is formed by a single layer of only one material or by multiple layers of various materials. In particular, the sealing layer 13 comprises one or more inorganic materials. The sealing layer 13 also may consist of one or more inorganic materials.

In the following, a method of manufacturing the microelectronic package 1 shown in FIG. 1 is described:

First of all, the anchor layer 6 and the first sacrificial layer are formed on top of the substrate 5. In particular, the first sacrificial layer may be applied on the substrate 5 and structured using photolithography, e.g. using a negative photoresist.

In a next step, the microelectronic structure 2 is formed on top of the first sacrificial layer and on top of the anchor layer 6. A first opening 3 is provided in the microelectronic structure 2.

In a next step, the spacer layer 12 and the second sacrificial layer are formed on top of the microelectronic structure 2. Then, the capping layer 9 is formed over the layer 12 and the second sacrificial layer. The capping layer 9 is formed using thin film technology. The capping layer 9 has the second opening 10. As discussed above, the second opening 10 is arranged over the first opening 3.

Next, the first and the second cavity 4, 11 are formed. For this purpose, the first and the second sacrificial layer are removed. The first and the second sacrificial layer are removed either in a common process step or in two separate process steps. The first and the second sacrificial layers are removed by etching with an etching atmosphere or by dissolving using a solvent. The etching atmosphere or the solvent enters through the second opening 10 and, respectively, the first opening 3. Moreover, the material of the first sacrificial layer and the material of the second sacrificial layer are removed through the first and the second opening 3, 10, thereby forming the first cavity 4 and the second cavity 11.

Afterwards, the second opening 10 is sealed with the sealing layer 13. The sealing layer 13 is formed via a thin film technology.

The above described manufacturing process is carried out on wafer level. Thus, a large number of microelectronic packages 1 can be manufactured simultaneously. The wafer is afterwards separated into a multitude of separate microelectronic packages 1.

### REFERENCE NUMBERS

1 microelectronic package

2 microelectronic structure

3 first opening

4 first cavity

5 substrate

6 anchor layer

7 free-standing element

8 actuator electrode

9 capping layer

10 second opening

11 second cavity

12 spacer layer

13 sealing layer

14 deposited material

1. Microelectronic package comprising
a microelectronic structure having at least a first opening and defining a first cavity,
a capping layer having at least a second opening and defining a second cavity which is connected to the first cavity, wherein the capping layer is arranged over the microelectronic structure such that the second opening is arranged over the first opening, and
a sealing layer covering the second opening, thereby sealing the first cavity and the second cavity.

2. Microelectronic package according to claim 1, wherein the second opening has a width which is smaller than a width of the first opening.

3. Microelectronic package according claim 1,
wherein the width of the first opening is at least twice as big as the width of the second opening.

4. Microelectronic package according to claim 1,
wherein the width of the first opening is at least five times as big as the width of the second opening.

5. Microelectronic package according to claim 1,
wherein the sealing layer comprises an inorganic material.

6. Microelectronic package according to claim 1,
wherein the sealing layer comprises one of silicon dioxide, silicon hydride or silicon nitride.

7. Microelectronic package according to claim 1,
wherein the capping layer comprises more than one second opening,
wherein the microelectronic structure comprises more than one first opening, and
wherein each of the second openings is arranged either over one of the first openings or arranged in a section of the capping layer which does not overlap with the microelectronic structure.

8. Method of manufacturing a microelectronic package, comprising the steps of:
providing a microelectronic structure having at least a first opening and defining a first cavity,
forming a capping layer over the microelectronic structure wherein the capping layer has at least a second opening and defines a second cavity which is connected to the first cavity and wherein the capping layer is arranged such that the second opening is arranged over the first opening, and
covering the second opening with a sealing layer, thereby sealing the first cavity and the second cavity.

9. Method according to claim 8,
wherein the sealing layer is formed via chemical vapor deposition.

10. Method according to claim 8,
wherein the method comprises a step of etching the first opening into the microelectronic structure and
wherein the method comprises a step of removing a first sacrificial layer to form the first cavity.

11. Method according to claim 8,
wherein the method comprises a step of etching the second opening into the capping layer and
wherein the method comprises a step of removing a second sacrificial layer to form the second cavity.

12. Method according to claim 8,
wherein the capping layer and the sealing layer are formed by a thin film technology.

13. Method according to claim 8,
wherein the sealing layer comprises an inorganic material.

14. Method of manufacturing a multitude of microelectronic packages,
wherein the following steps are carried out on a wafer level:
providing microelectronic structures having at least a first opening and defining a first cavity,
forming a capping layer over the microlectronic structures wherein the capping layer has at least a second opening and defines a second cavity which is connected to the first cavity and wherein the capping layer is arranged such that the second opening is arranged over the first opening, and
covering the second opening with a sealing layer, thereby sealing the first cavity and the second cavity, and
wherein the wafer is, afterwards, separated into the multitude of microelectronic packages.
